(19) United States
(12) Patent Application Publication
(10) Pub. No.: US 2026/0020199 A1
(43) Pub. Date: Jan. 15, 2026

(54) POWER CONVERSION APPARATUS, AND MANUFACTURING METHOD FOR POWER CONVERSION APPARATUS

(71) Applicant: HITACHI ASTEMO, LTD., Hitachinaka-shi, Ibaraki (JP)

(72) Inventors: Naoya TOKOO, Hitachinaka-shi, Ibaraki (JP); Toshiaki ISHII, Hitachinaka-shi, Ibaraki (JP); Rinnosuke ODA, Hitachinaka-shi, Ibaraki (JP)

(73) Assignee: HITACHI ASTEMO, LTD., Hitachinaka-shi, Ibaraki (JP)

(21) Appl. No.: 18/993,267

(22) PCT Filed: Jul. 28, 2022
(86) PCT No.: PCT/JP2022/029211

§ 371 Date: Jan. 10, 2025

(51) Int. Cl. H05K 7/20; H02M 3/00

(52) U.S. Cl. CPC H05K 7/209; H02M 3/003

(57) ABSTRACT

A power conversion apparatus includes: a semiconductor element; a heat exchanger plate connected to the semiconductor element; a semiconductor module formed by molding the semiconductor element and the heat exchanger plate with resin; a thermal conductive material having a semisolid shape that is disposed in contact with the heat exchanger plate and covering one surface of the semiconductor module; and a heat dissipation member that dissipates heat from the semiconductor module through the thermal conductive material.

### TECHNICAL FIELD

The present invention relates to a power conversion apparatus, and a manufacturing method for a power conversion apparatus.

### BACKGROUND ART

In a power conversion apparatus having a double-sided cooling structure, a thermal conductive material such as a thermal interface material (TIM) is disposed between the power conversion apparatus and a cooling water channel that is a heat dissipation member, and depending on a contact situation between this thermal conductive material and a lead frame (heat exchanger plate) included in a semiconductor module, reliability of the apparatus may deteriorate. The power conversion apparatus is also required to reduce cost and improve productivity.

PTL 1 described below discloses an apparatus having a structure in which heat generated in a semiconductor element is efficiently dissipated to the outside by providing a heat transfer layer on an upper surface of the semiconductor element.

### CITATION LIST

### Patent Literature

PTL 1: JP No. 5740995.

### SUMMARY OF INVENTION

### Technical Problem

The structure described in PTL 1 has a possibility that a TIM, which is a heat transfer layer (thermal conductive material), pumps out, and this causes a problem that thermal resistance increases or insulation quality decreases. In view of this, an object of the present invention is to provide a power conversion apparatus and a manufacturing method for the power conversion apparatus that achieve cost reduction, improvement of productivity, and improvement of reliability.

### Solution to Problem

A power conversion apparatus includes: a semiconductor element; a heat exchanger plate connected to the semiconductor element; a semiconductor module formed by molding the semiconductor element and the heat exchanger plate with resin; a thermal conductive material having a semisolid shape that is disposed in contact with the heat exchanger plate and covering one surface of the semiconductor module; and a heat dissipation member that dissipates heat from the semiconductor module through the thermal conductive material.

As a manufacturing method for a power conversion apparatus, a method is adopted, the method including: forming a semiconductor module by molding, with a resin, a semiconductor element and a heat exchanger plate connected to the semiconductor element; forming a stepped portion formed to expose a surface of the heat exchanger plate and surround the surface of the heat exchanger plate by removing a part of a mold resin of one surface of the semiconductor module having been formed; and assembling, to the semiconductor module, a thermal conductive material having a semisolid shape disposed in contact with an exposure surface of the heat exchanger plate and covering the mold resin on the one surface, and a heat dissipation member that dissipates heat from the semiconductor module via the thermal conductive material.

### Advantageous Effects of Invention

It is possible to provide a power conversion apparatus and a manufacturing method for the power conversion apparatus that achieve cost reduction, improvement of productivity, and improvement of reliability.

### BRIEF DESCRIPTION OF DRAWINGS

FIG. 1 is a circuit diagram of a power conversion apparatus.

FIG. 2 is an overall view of the power conversion apparatus.

FIG. 3 is a cross-sectional view of a power conversion apparatus according to one embodiment of the present invention.

FIG. 4 is a view describing a first manufacturing method for the power conversion apparatus.

FIG. 5 is a view describing a second manufacturing method for the power conversion apparatus.

FIG. 6 is a view describing a positional relationship between a first thermal conductive material and a semiconductor module.

FIG. 7 is a view describing a positional relationship between a second thermal conductive material and a semiconductor module.

Hereinafter, an embodiment of the present invention will be described with reference to the drawings. The following description and drawings are examples for describing the present invention, and are omitted and simplified as appropriate for the sake of clarity of description. The present invention can be carried out in various other forms. Unless otherwise specified, each constituent element may be singular or plural.

The positions, sizes, shapes, ranges, and the like of the constituent elements illustrated in the drawings do not always represent actual positions, sizes, shapes, ranges, and the like, for the sake of easy understanding of the invention. Therefore, the present invention is not necessarily limited to the positions, sizes, shapes, ranges, and the like disclosed in the drawings.

### One embodiment of Present Invention and Overall Configuration

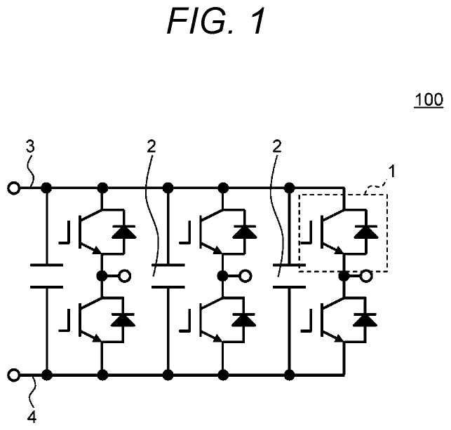

### (FIG. 1)

In a power conversion apparatus 100, each of a plurality of circuit bodies 1 constituting a power conversion circuit is constituted by a semiconductor element such as an insulated gate bipolar transistor (IGBT) or a metal-oxide-semiconductor field-effect transistor (MOSFET). Two circuit bodies 1 connected in series and one capacitor 2 are paired to form a power conversion circuit for one phase. A three-phase power conversion circuit is connected to a positive electrode wire 3 and a negative electrode wire 4, respectively.

The circuit body 1 (semiconductor module 1) has three terminals of a main circuit high-voltage side terminal (collector terminal for IGBT, and drain terminal for MOSFET), a main circuit low-voltage side terminal (emitter terminal for IGBT, and source terminal for MOSFET), and a control terminal (gate terminal).

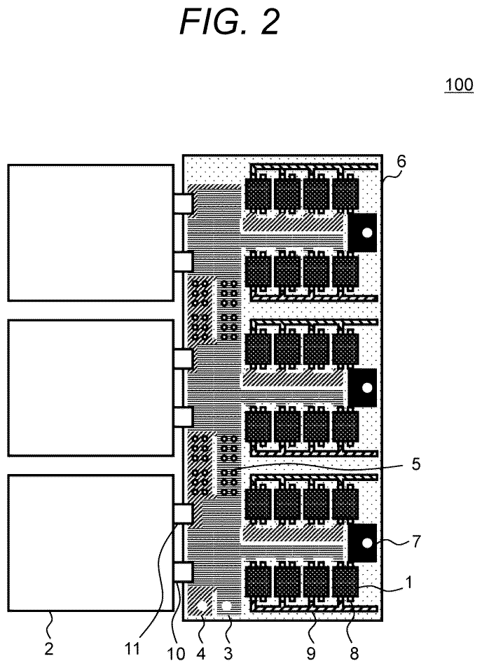

### (FIG. 2)

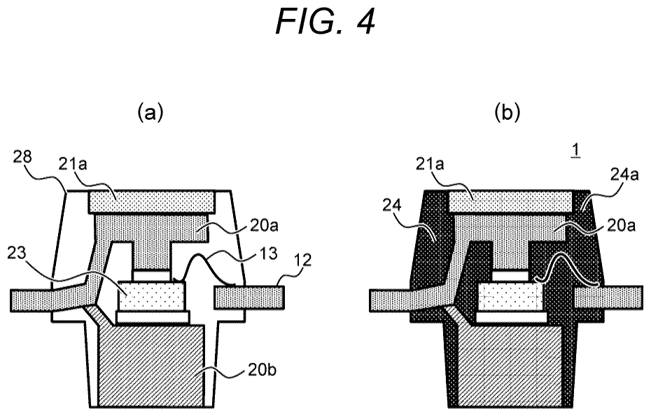

The power conversion apparatus 100 includes the plurality of circuit bodies 1 each having a plurality of power semiconductor elements, a wire board 6 (hereinafter, board 6) electrically connected to the circuit bodies 1 and provided with a plurality of the positive electrode wires 3 and a plurality of the negative electrode wires 4 stacked on each other in a thickness direction, and a plurality of smoothing capacitors 2 provided corresponding to the plurality of circuit bodies 1, respectively. The positive electrode wires 3 and the negative electrode wires 4 are stacked on each other in a thickness direction of the board 6 (front-back direction of the sheet of FIG. 2), and connect the capacitor 2 of each phase and the circuit body 1 (details will be described later with reference to FIGS. 4 to 7).

FIG. 2 illustrates a configuration example of circuits for three phases provided on the board 6 with eight circuit bodies 1 being a circuit of one phase in which the circuit bodies 1 are arranged in parallel as groups of four, and arranged so as to face each other across the positive electrode wire 3 and the negative electrode wire 4. In this manner, the circuit bodies 1 may be arranged in multiple parallel connections according to a desired output current value. Similarly, in order to satisfy a capacitor capacitance determined depending on a desired input voltage fluctuation amount, the capacitors 2 may be connected on the board 6 in multiple parallel connections.

The board 6 has a plurality of conductor layers in the thickness direction, and each conductor layer is stacked via a resin layer. The conductor layer of the board 6 has the positive electrode wire 3, the negative electrode wire 4, an output wire 7, and a signal wire 9 that are formed therein. The circuit body 1 and the capacitor 2 are connected to the positive electrode wire 3 and the negative electrode wire 4 by a bonding material such as solder. The circuit body 1 has a signal terminal 8 for connecting with the signal wire 9. Each of the positive electrode wire 3, the negative electrode wire 4, and the output wire 7 is formed thicker than the signal wire 9 connected to the circuit body 1, and has a configuration corresponding to that the current to be supplied to a load of a connection destination is larger than that in other wires.

The positive electrode wire 3 and the negative electrode wire 4 have a through via 5 (hereinafter, via 5). The via 5 is provided in a region where the positive electrode wires 3 and the negative electrode wires 4 of each phase are not stacked on each other. Each of the plurality of positive electrode wires 3 or the plurality of negative electrode wires 4 penetrates in the thickness direction of the board 6 to form the via 5, whereby wires having the same potential are electrically conducted to each other. This suppresses a decrease in the cross-sectional area of the positive electrode wire 3 and the negative electrode wire 4 in a region not provided with the via 5, and suppresses the positive electrode wire 3 and the negative electrode wire 4 from being divided in a region provided with the via 5.

Note that when using a blind via for the via 5, by making the first layer and the second layer from the upper surface (the surface on the front side in FIG. 2) of the board 6 formed of four layers as the positive electrode wire 3 and the third layer and the fourth layer as the negative electrode wire 4, it is possible to stack the positive electrode wires 3 and the negative electrode wires 4 without reducing the cross-sectional areas of the positive electrode wire 3 and the negative electrode wire 4.

The positive electrode wire 3 is connected to a positive electrode terminal of a direct-current voltage source such as a battery not illustrated, and the negative electrode wire 4 is connected to a negative electrode terminal of a direct-current voltage source such as a battery not illustrated. Due to this, the circuit of each phase is supplied with a direct-current voltage.

The capacitors 2 are connected side by side along the board 6 in order to satisfy a capacitor capacitance determined depending on a desired input voltage fluctuation amount, and includes a positive electrode terminal 10 and a negative electrode terminal 11 as terminals for connecting to the positive electrode wire 3 and the negative electrode wire 4 of the board 6.

The positive electrode terminal 10 of the capacitor 2 is electrically connected to the main circuit high-voltage side terminal of the circuit body 1 on the high side (upper arm) side by being connected to the positive electrode wire 3. The positive electrode wire 3 is connected to the positive electrode terminal 10 of the capacitor 2 of the other phase and a main circuit high-voltage side terminal of the circuit body 1 of the high side of the other phase. The negative electrode terminal 11 of the capacitor 2 is connected to the main circuit low-voltage side terminal of the circuit body 1 on the low side (lower arm) side by being connected to the negative electrode wire 4. The negative electrode wire 4 is connected to the negative electrode terminal 11 of the capacitor 2 of the other phase and a main circuit low-voltage side terminal 12 of the circuit body 1 of the low side of the other phase. The main circuit low-voltage side terminal of the circuit body 1 of the high side is connected to the main circuit high-voltage side terminal of the circuit body 1 of the low side by the output wire 7 of each phase. The output wire 7 of each phase is connected to a load such as a motor not illustrated.

The control terminal of the circuit body 1 is connected to a control circuit not illustrated, and is turned on or off based on a signal input from a high-order control apparatus such as a microcomputer, thereby outputting an alternating-current voltage to a load such as a motor.

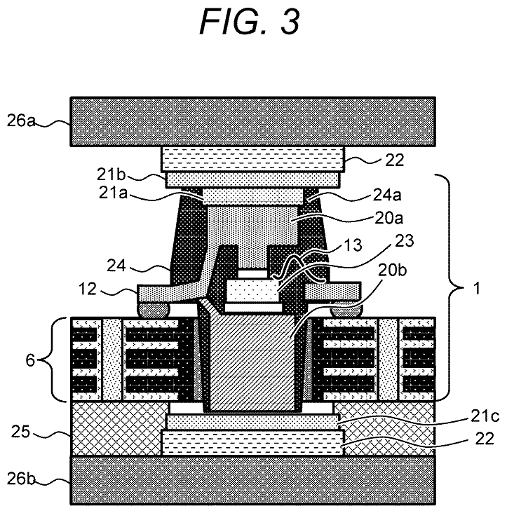

### (FIG. 3)

FIG. 3 is a cross-sectional view illustrating the configuration of the circuit body 1 (hereinafter, semiconductor module 1). The semiconductor module 1 includes a semiconductor element 23 and a heat exchanger plate 20 (lead frame 20). The semiconductor element 23 and the heat exchanger plate 20 are molded by a resin 24 (resin). The semiconductor element 23 is connected to the heat exchanger plate 20 via solder on both chip surfaces. Note that the connection between the semiconductor element 23 and the heat exchanger plate 20 is not limited to solder, and a sintered material, a hybrid material of metal and resin, or the like may be used. A gate pad not illustrated on the chip upper surface of the semiconductor element 23 and a lead terminal 12 are connected by wire bonding 13.

The lead terminal 12 protruding from the heat exchanger plate 20 to the outside is connected to the board 6 by solder. In the heat exchanger plate 20, the heat exchanger plate 20 (source side) on the upper side in FIG. 3 is a first heat exchanger plate 20a, and the lower side is a second heat exchanger plate 20b.

Two thermal conductive materials 21a and 21b are disposed on the upper surface of the first heat exchanger plate 20a. The thermal conductive materials 21a and 21b are, for example, TIMs. The thermal conductive materials 21a and 21b are thermal conductive materials having a semisolid shape disposed in contact with the first heat exchanger plate 20a and covering one surface of the semiconductor module 1. Note that the thermal conductive material having the semisolid shape refers to a thermal conductive material made of a material such as a filler or grease and deformed in shape by being pressed.

The thermal conductive materials 21a and 21b are in contact with an insulation sheet 22 on a surface (surface of the second thermal conductive material 21b) opposite to a surface (surface of the first thermal conductive material 21a) in contact with the heat exchanger plate 20a. The insulation sheet 22 is in contact with a first cooling water channel 26a on a surface opposite to a surface in contact with the second thermal conductive material 21b. With such a structure, heat generated from the semiconductor module 1 is dissipated by the first cooling water channel 26a, which is a heat dissipation member, via the thermal conductive materials 21a and 21b.

This semiconductor module 1 has a stepped portion 24a formed so as to surround the periphery of the first thermal conductive material 21a on one surface (upper surface side) in contact with the thermal conductive materials 21a and 21b. The stepped portion 24a is formed by processing a part of the mold resin 24 at an upper surface end portion of the of the semiconductor module 1. The stepped portion 24a has two protrusion shapes in the cross-sectional view of FIG. 3. Of the thermal conductive materials 21a and 21b, the first thermal conductive material 21a is disposed on the inner side of the stepped portion 24a, whereby the first thermal conductive material 21a is disposed such that the periphery thereof is surrounded by the stepped portion 24a. On the other hand, the second thermal conductive material 21b has an area larger than that of the first thermal conductive material 21a. Note that from the viewpoint of mold releasability, when the protrusion portion of the stepped portion 24a is formed by die cutting, the draft angle of the die is desirably 3 degrees or more.

The height of the semiconductor module 1 including the heat exchanger plate 20 to which the chip of the semiconductor element 23 is soldered varies in a range of less than 100 μm as a result of trial and study. Therefore, from the viewpoints of thermal resistance and material cost, the thickness of the first thermal conductive material 21a is desirably 100 μm or less. The second thermal conductive material 21b can reduce the thermal resistance as thin as possible from the viewpoint of pump out, but at the same time, it is also necessary to absorb variation in the height of the upper surface of the stepped portion 24a of the semiconductor module 1 mounted on the board 6. Therefore, the thickness of the second thermal conductive material 21b is desirably 100 μm or less.

The semiconductor module 1 is in contact with a third thermal conductive material 21c via the heat exchanger plate 20b on a surface lower (lower side in FIG. 3) than the board 6. The board 6 is in contact with a heat dissipation sheet 25 on the lower surface of FIG. 3. The heat dissipation sheet 25 is in contact with a second cooling water channel 26b on a surface opposite to the surface in contact with the circuit board 6. With such a structure, both surfaces of the semiconductor module 1 are covered with the thermal conductive materials 21a, 21b, and 21c, and heat generated from the semiconductor module 1 and the board 6 is dissipated by the cooling water channels 26a and 26b arranged by sandwiching the semiconductor module 1 from both surfaces.

Note that the first thermal conductive material 21a and the second thermal conductive material 21b, which are two thermal conductive materials, may be integrated and disposed on one surface of the semiconductor module 1 as one thermal conductive material 21.

### First Manufacturing Method for Power Conversion Apparatus

### (FIG. 4)

FIG. 4(a) is a view illustrating an example of a first manufacturing method, and FIG. 4(b) is a view after the resin mold flows into the die of FIG. 4(a) and is cured. The semiconductor element 23 is connected to the first heat exchanger plate 20a by soldering, and the semiconductor element 23 and the lead terminal 12 are subjected to the wire bonding 13. Furthermore, the first thermal conductive material 21a having a semisolid shape is disposed in contact with the first heat exchanger plate 20a between a frame of a die 28 and the first heat exchanger plate 20a. As described above, after the heat exchanger plates 20a and 20b, the semiconductor element 23, and the first thermal conductive material 21a are set in the die 28, transfer molding is performed with the resin 24. This can form the semiconductor module 1 including the stepped portion 24a on one surface and having the surface of the first heat exchanger plate 20a exposed.

In this manner, since the first thermal conductive material 21a is set in the die 28 in a state of being disposed before resin molding, it is possible to prevent overmolding in which a gap is not generated between the first heat exchanger plate 20a and the die 28 and thermal resistance increases. Grinding and cleaning processes performed to eliminate the overmolding occurring by a state in which the first thermal conductive material 21a is not disposed before the resin molding are simplified. Metal pieces and residues remain after cleaning, and it is possible to prevent deterioration of insulation quality and peeling of the first thermal conductive material 21a. In this manner, according to the manufacturing method of the present invention, it is possible to provide the semiconductor module 1 in a state where one electrode surface of the heat exchanger plate 20 is exposed at a stage when resin molding is completed.

The semiconductor module 1 produced by this manufacturing method is mounted on the board 6, the second thermal conductive material 21b is further brought into contact with the upper surface (one surface) of the semiconductor module 1, the third thermal conductive material 21c is brought into contact with the lower surface (other surface), each is attached with the insulation sheet 22, and finally, the semiconductor module 1 is sandwiched from above and below by the cooling water channels 26a and 26b. Due to this, the power conversion apparatus 100 is completed.

Conventionally, when the semiconductor module 1 having no stepped portion 24a is formed after resin molding, there has been a problem that thermal resistance increases due to occurrence of pump out or generation of voids. However, by assembling the semiconductor module 1 by the manufacturing method of the present invention, the first thermal conductive material 21a is sandwiched with the stepped portions 24a, and the second thermal conductive material 21b is disposed on the upper surface thereof, and therefore, pump out of the second thermal conductive material 21b can be suppressed.

### Second Manufacturing Method for Power Conversion Apparatus

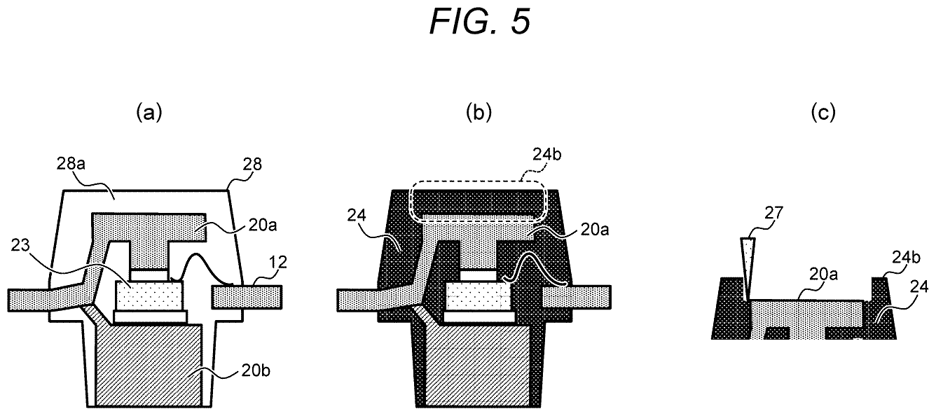

### (FIG. 5)

FIGS. 5(a) to 5(c) are views describing a second manufacturing method. First, in FIG. 5(a), the semiconductor element 23 and the lead terminal 12 connected to the first heat exchanger plate 20a and the second heat exchanger plate 20b, respectively, are mounted to the die 28. At this time, a gap 28a is generated between the heat exchanger plate 20a and the die 28 due to variation in solder thickness, inclination of the first heat exchanger plate 20a, and the like.

Subsequently, in FIG. 5(b), the resin 24 is poured into the die 28 to perform transfer molding. Due to this, the resin flows into the gap 28a on the first heat exchanger plate 20a illustrated in FIG. 5(a), and the semiconductor module 1 in which the part that is overmolded 24b is formed is obtained. Then, in FIG. 5(c), only the resin 24 that is a part of the mold resin 24 on one surface of the semiconductor module 1 and is overmolded 24b on the upper side of the heat exchanger plate 20a is removed by, for example, a laser decapper 27. By performing this process, it is possible to provide the semiconductor module 1 in a state where the stepped portion 24a provided so as to surround the heat exchanger plate 20a is formed and one electrode surface of the heat exchanger plate 20a is exposed.

The thermal conductive materials 21a and 21b having semisolid shapes disposed in contact with the exposure surface of the heat exchanger plate 20a of the semiconductor module 1 and covering the mold resin 24 on one surface, and cooling water channels 26a and 26b, which are heat dissipation members that dissipate heat to the semiconductor module 1 via the thermal conductive materials 21a and 21b, are assembled to the semiconductor module 1 manufactured as described above. By doing so, the power conversion apparatus 100 of the present invention can be provided.

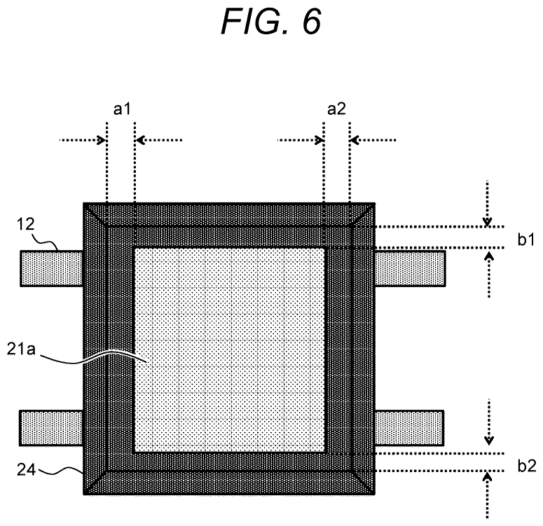

### (FIG. 6)

In the resin 24 of the semiconductor module 1, the following relationship is established between the stepped portion 24a and the first thermal conductive material 21a. The widths of the stepped portion 24a in the direction with the lead terminal 12 are widths a1 and a2 from the left in FIG. 6, and the widths of the stepped portion 24a in the direction without the lead terminal 12 are widths b1 and b2 from the top in FIG. 6. At this time, a1>b1 or a1>b2. Furthermore, a2>b1 or a2>b2. Due to this, conventionally, the second thermal conductive material 21b has a problem that a part of the thermal conductive material 21 pumped out falls between the lead terminals 12, thereby causing a decrease in insulation quality, but according to the present invention, the thermal conductive material 21 is less likely to pump out, and the resistance of the cooling water channel 26 increases. Even if the thermal conductive material 21b is pumped out and falls down, it falls preferentially to the direction without the lead terminal 12, and therefore the insulation quality does not deteriorate.

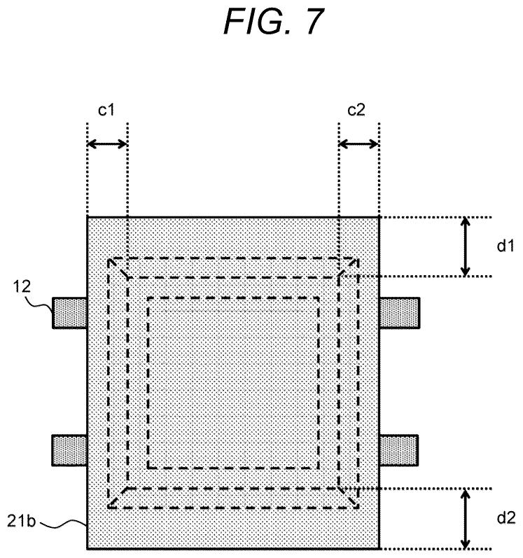

### (FIG. 7)

Regarding the second thermal conductive material 21b in contact with the upper surface of the semiconductor module 1, the following relationship is established for the length of the second thermal conductive material 21b protruding from the stepped portion 24a of the semiconductor module 1. The distances by which the second thermal conductive material 21b protrudes from the stepped portion 24a in the direction with the lead terminal 12 are c1 and c2 from the left in FIG. 7, and the distances by which the second thermal conductive material 21b protrudes from the stepped portion 24a in the direction without the lead terminal 12 are defined as d1 and d2 from the top in FIG. 7. At this time, 0<c1<d1 or 0<c1<d2. In addition, 0<c2<d1 or 0<c2<d2. Due to this, even if the second thermal conductive material 21b is pumped out and falls down, it falls preferentially to the direction without the lead terminal 12, and therefore the insulation quality of the lead terminal 12 does not deteriorate.

According to one embodiment of the present invention described above, the following operational effects are achieved.
(1) The semiconductor element 23; the heat exchanger plates 20a and 20b connected to the semiconductor element 23; the semiconductor module 1 formed by molding the semiconductor element 23 and the heat exchanger plates 20a and 20b with the resin 24; the thermal conductive materials 21a and 21b each having a semisolid shape that is disposed in contact with the heat exchanger plates 20a and 20b and covering one surface of the semiconductor module 1; and the heat dissipation member 26 that dissipates heat from the semiconductor module via the thermal conductive materials 21a and 21b are included. This can provide the power conversion apparatus 100 that achieves cost reduction, improvement of productivity, and improvement of reliability.
(2) The semiconductor module 1 has the stepped portion 24a formed so as to surround the periphery of a part (first thermal conductive material 21a) of the thermal conductive materials 21a and 21b on one surface in contact with the thermal conductive materials 21a and 21b having the semisolid shapes. This can suppresses pump out and provide the semiconductor module 1 in a state where one electrode surface of the heat exchanger plate 20a is exposed.
(3) The thermal conductive material 21 includes the first thermal conductive material 24a disposed such that the periphery of the first thermal conductive material 21a is surrounded by the stepped portion 24a, and the second thermal conductive material 21b in contact with the first thermal conductive material 21a and having an area larger than an area of the first thermal conductive material 21a. By doing this, both surfaces of the semiconductor module 1 are covered with the thermal conductive material 21, and heat generated from the semiconductor module 1 and the board 6 is dissipated by the cooling water channels 26a and 26b arranged by sandwiching the semiconductor module 1 from both surfaces.
(4) The first thermal conductive material 21a and the second thermal conductive material 21b are integrally disposed on one surface of the semiconductor module 1. This improves the connectivity between the first thermal conductive material 21a and the second thermal conductive material 21b, and contributes to the heat dissipation of the semiconductor module 1.
(5) One surface of the semiconductor module 1 has a surface of the thermal conductive material 21a exposed, and the other surface of the semiconductor module 1 is in contact with the third thermal conductive material 21c different from the thermal conductive material 21a, and the third thermal conductive material 21c is in contact with the second heat dissipation member 26b different from the heat dissipation member 26a on the surface opposite to the surface in contact with the semiconductor module 1. This can provide the power conversion apparatus 100 in which both surfaces of the semiconductor module 1 are cooled.
(6) The manufacturing method for the power conversion apparatus 100 of the present invention includes: forming the semiconductor module 1 by molding, with the resin 24, the semiconductor element 23 and the heat exchanger plates 20a and 20b connected to the semiconductor element 23; forming the stepped portion formed to expose the surface of the heat exchanger plate 20a and surround the surface of the heat exchanger plate by removing a part of the mold resin 24 of one surface of the formed semiconductor module 1 having been formed; and assembling, to the semiconductor module 1, the thermal conductive material 21a having the semisolid shape disposed in contact with the exposure surface of the heat exchanger plate 20a and covering the mold resin 24 on the one surface, and the heat dissipation member 26 that dissipates heat from the semiconductor module 1 via the thermal conductive material 21a. This can manufacture the power conversion apparatus 100 that achieves cost reduction, improvement of productivity, and improvement of reliability.

Note that the present invention is not limited to the above embodiment, and various modifications and other configurations can be combined without departing from the gist of the present invention. The present invention is not limited to one including all the configurations described in the above embodiment, and includes one in which a part of the configuration is deleted.

### Reference Signs List

1 circuit body (semiconductor module)
2 capacitor
3 positive electrode wire
4 negative electrode wire
5 via
6 wire board
6a center line
7 output wire
8 signal terminal
9 signal wire
10 capacitor positive electrode terminal
11 capacitor negative electrode terminal
12 lead terminal
13 wire bonding
20 heat exchanger plate (lead frame)
20a first heat exchanger plate
20b second heat exchanger plate
21 thermal conductive material (TIM)
21a first thermal conductive material
21b second thermal conductive material
21c third thermal conductive material
22 insulation sheet
23 semiconductor element (chip)
24 mold resin (mold resin)
24a stepped portion (protrusion portion)
24b overmold
25 heat dissipation sheet
26 cooling water channel (heat dissipation member)
26a first cooling water channel
26b second cooling water channel
27 laser decapper
28 die
28a gap between die and lead frame
100 power conversion apparatus
a1 Width of upper surface of stepped portion in direction with lead terminal
b1 Width of upper surface of stepped portion in direction without lead terminal
c1 distance in which second heat dissipation member protrudes in direction with lead terminal
d1 distance in which second heat dissipation member protrudes in direction without lead terminal

1. A power conversion apparatus comprising:
a semiconductor element;
a heat exchanger plate connected to the semiconductor element;
a semiconductor module formed by molding the semiconductor element and the heat exchanger plate with resin;
a thermal conductive material having a semisolid shape that is disposed in contact with the heat exchanger plate and covering one surface of the semiconductor module; and
a heat dissipation member that dissipates heat from the semiconductor module through the thermal conductive material.

2. The power conversion apparatus according to claim 1, wherein
the semiconductor module has a stepped portion formed so as to surround a periphery of a part of the thermal conductive material on the one surface in contact with the thermal conductive material having the semisolid shape.

3. The power conversion apparatus according to claim 2, wherein
the thermal conductive material includes a first thermal conductive material disposed such that a periphery of the first thermal conductive material is surrounded by the stepped portion, and a second thermal conductive material in contact with the first thermal conductive material and having an area larger than an area of the first thermal conductive material.

4. The power conversion apparatus according to claim 3, wherein
the first thermal conductive material and the second thermal conductive material are integrally disposed on the one surface of the semiconductor module.

5. The power conversion apparatus according to claim 1, wherein
one surface of the semiconductor module has a surface of the thermal conductive material exposed, and an other surface of the semiconductor module is in contact with a third thermal conductive material different from the thermal conductive material, and
the third thermal conductive material is in contact with a second heat dissipation member different from the heat dissipation member on a surface opposite to a surface in contact with the semiconductor module.

6. A manufacturing method for a power conversion apparatus, comprising:
forming a semiconductor module by molding, with a resin, a semiconductor element and a heat exchanger plate connected to the semiconductor element;
forming a stepped portion formed to expose a surface of the heat exchanger plate and surround the surface of the heat exchanger plate by removing a part of a mold resin of one surface of the semiconductor module having been formed; and
assembling, to the semiconductor module, a thermal conductive material having a semisolid shape disposed in contact with an exposure surface of the heat exchanger plate and covering the mold resin on the one surface, and a heat dissipation member that dissipates heat from the semiconductor module via the thermal conductive material.
